(19) United States
(12) Patent Application Publication
(10) Pub. No.: US 2015/0171319 A1
(43) Pub. Date: Jun. 18, 2015

(54) RESISTANCE CHANGE MEMORY ELEMENT

(71) Applicant: TAIYO YUDEN CO., LTD., Tokyo (JP)

(72) Inventors: Seisuke Nigo, Chiba (JP); Mitsunori Katsu, Tokyo (JP); Masayuki Sato, Tokyo (JP); Yuichi Sasajima, Tokyo (JP)

(73) Assignee: TAIYO YUDEN CO., LTD., Tokyo (JP)

(21) Appl. No.: 14/418,021

(22) PCT Filed: Aug. 11, 2013
(86) PCT No.: PCT/JP2013/071742

§ 371 Date: Jan. 28, 2015

(30) Foreign Application Priority Data
Aug. 31, 2012 (JP) 2012-192699

(51) Int. Cl. H01L 45/00; G11C 13/00

(52) U.S. Cl. CPC H01L 45/1206; G11C 13/0097; H01L 45/1226; H01L 45/146; H01L 45/08

(57) ABSTRACT

Provided is a resistive-switching memory device that includes: a resistive-switching insulating film; a source electrode arranged on a first main surface of the resistive-switching insulating film; a drain electrode arranged on the first main surface; and a gate electrode arranged on a second main surface of the resistive-switching insulating film, the second main surface being opposite to the first main surface.

### TECHNICAL FIELD

The present invention relates to a resistive-switching memory device.

### BACKGROUND

Currently, the standard types of readable and writeable memories used are SRAM (static random access memory), DRAM (dynamic RAM), and flash memory. SRAM, in addition to having the disadvantage of being volatile, also cannot be made high capacity due to difficulties in high integration, but can be accessed at high speed, and is thus used in cache memory or the like. DRAM also has the disadvantage of being volatile, and additionally is of a destructive read type, which means that it needs to be reflashed every time it is read, but is often used as the main memory in personal computers due to the advantage of being able to be highly integrated. Flash memory can store data even after the power source is cut off, and is used for storage of data taking up a relatively small amount of space, but the read time thereof is longer than for DRAM.

New types of memory are being developed for high performance in contrast to these standard types of memory. For example, a non-volatile memory that stores data by using a changeable resistor in which the electrical resistance thereof is reversibly changed by applying a voltage thereon is proposed (also referred to as a ReRAM (resistive random access memory)).

The ReRAM element has a structure including a lower electrode, a resistive-switching insulating film, and an upper electrode stacked in this order, and has the property of being able to reversibly change the resistance of the resistive-switching insulating film by applying a voltage pulse between the upper electrode and the lower electrode. By reading the resistance switched by the reversible resistance switching operation, a resistive-type non-volatile memory is realized. A memory cell array is formed by arranging ReRAM elements in a matrix, and a peripheral circuit is provided to control the writing, deletion, and reading of data from the memory cells of the memory cell array, thereby forming the ReRAM.

The research and development of ReRAM involves innovations and the like in the metal oxide film that undergoes a change in resistance, and materials for the electrode metal suited to this (Patent Document 1, Patent Document 2, and Non-Patent Document 1).

### RELATED ART DOCUMENTS

### Patent Documents

Patent Document 1: Japanese Patent Application Laid-Open Publication No. 2012-33649

Patent Document 2: Japanese Patent Application Laid-Open Publication No. 2005-183570 Patent Document 3: Japanese Patent Application Laid-Open Publication No. 2010-15662

### Non-Patent Documents

Non-Patent Document 1: Z. Wei, T. Takagi et al. IEDM (2008) Highly Reliable TaOx ReRAM and Direct Evidence of Redox Reaction Mechanism

Non-Patent Document 2: H. Momida, S. Nigo et al. APL. 98, 042102 (2011) Effect of vacancy-type oxygen deficiency on electronic structure in amorphous alumina

Non-Patent Document 3: T. W. Hickmott APL. 88, 2805 (2000) Voltage-depend dielectric breakdown and Voltage-controlled negative resistance in anodized Al—Al₂O₃—Au diodes

Non-Patent Document 4: T. W. Hickmott APL. 100, 083712 (2006) A breakdown mechanism in metal-insulator-metal structures

### SUMMARY OF THE INVENTION

### Problems to be Solved by the Invention

The disclosed ReRAM has a two-electrode structure in which the insulator is sandwiched by two electrodes at the front and rear of the insulator, and relies on the phenomenon of the insulator changing resistance due to the application of voltage. The reason is that the two-electrode structure is simple, which allows for memory integration with ease, and the Schottky barrier, which necessarily occurs between the metal oxide film and the electrode metal, fulfills the important function of switching while current is carried through a large number of carriers, thereby attaining the advantage of high speed operation.

The structure of sandwiching the insulator with two electrodes from the front and rear is suited to highly integrating the memory. However, if ReRAM is used together with other semiconductor elements, wiring lines need to be provided both on the front and rear, which means wiring lines cannot be formed all at once, and because the distance between wiring lines is the same as the thickness of the resistive-switching film, insulation failure sometimes occur between wiring lines, which means that it is difficult to use ReRAM together with other semiconductor elements.

### Means for Solving the Problems

Aspects for solving the above-mentioned problem include items (1) to (6) below:

(1) A resistive-switching memory device, including:

a resistive-switching insulating film;

a source electrode disposed on a first main surface of the resistive-switching insulating film;

a drain electrode disposed on the first main surface; and

a gate electrode disposed on a second main surface of the resistive-switching insulating film opposite to the first main surface.

Because the source electrode and the drain electrode are provided on the same surface, electrode wiring lines can be provided on the same surface, which means that insulation between the wiring lines can be ensured by adjusting the gap between the wiring lines in a planar manner, which means that this device can be used together with other semiconductor elements.

(2) The resistive-switching memory device according to item 1, further including: an insulating film between the source electrode and the drain electrode.

An insulating film is included between the two metal electrodes and the junction is charged or discharged every time the electrons are tunneled, and as a result, the junction voltage increases or decreases, thereby writing (sometimes referred to as the “ON operation”) or deleting (sometimes referred to as an “OFF operation”) data. By this configuration, it is possible to make the OFF current smaller than by using a two-electrode type resistive-switching memory device turned OFF by a normal current.

(3) The resistive-switching memory device according to item 1 or 2, wherein deletion of data is performed by setting a potential of the gate electrode greater than a potential of the source electrode and the drain electrode.

By turning OFF the resistive-switching memory device by applying a voltage from the gate electrode to the resistive-switching insulating film, a stored charge is extracted from the resistive-switching insulating film without passing a current between the source electrode and the drain electrode, which can reduce the OFF current.

(4) The resistive-switching memory device according to any one of items 1 to 3, wherein the source electrode and the drain electrode are arranged in a direction perpendicular to a direction in which the resistive-switching insulating film is stacked.

The operating current flows in the direction of the surface of the resistive-switching insulating film on which elements are stacked, thereby attaining an interface effect whereby oxygen vacancy occurs with ease in the interface, and thus, compared to a conventional configuration in which current flows through the stacked surfaces, the current flows through with greater ease, which not only allows high speed operation but mitigates damage to the resistive-switching insulating film.

(5) The resistive-switching memory device according to any one of items 1 to 4, wherein the resistive-switching insulating film is an aluminum oxide film or a metal oxide film of a metal other than a transition metal, and has oxygen vacancies (Vo) at a density of 2×10²¹ cm⁻³ or greater.

(6) The resistive-switching memory device according to item 5, wherein the transition metal is Zn, In, or Ga.

### Effects of the Invention

The resistive-switching memory of one embodiment of the present invention has the source electrode and the drain electrode provided on the same edge face as the resistive-switching insulating film, thus presenting the effect of making it easier to use the resistive-switching memory together with other semiconductor elements.

### BRIEF DESCRIPTION OF THE DRAWINGS

FIG. 1 is a cross-sectional view showing one example of a two-electrode type resistive-switching memory device.

FIG. 2 is a cross-sectional view showing one example of a three-electrode type resistive-switching memory device.

FIG. 3 is a cross-sectional view showing another example of a three-electrode type resistive-switching memory device.

FIG. 4A shows an example of a two-electrode type resistive-switching memory device provided with a circuit for measuring current-voltage (IV) characteristics.

FIG. 4B shows an example of IV characteristics of the two-electrode type resistive-switching memory device.

FIG. 5A shows an example of a three-electrode type resistive-switching memory device provided with a circuit for measuring IV characteristics.

FIG. 5B shows an example of IV characteristics of the three-electrode type resistive-switching memory device.

FIG. 6A is a drawing for describing the ON/OFF mechanism of a two-electrode type resistive-switching memory device.

FIG. 6B is a drawing for describing the ON/OFF mechanism of a three-electrode type resistive-switching memory device.

### DETAILED DESCRIPTION OF EMBODIMENTS

Embodiments of the present invention will be explained below with reference to the drawings.

(1) Configuration of Two-Electrode Type Resistive-Switching Memory Device

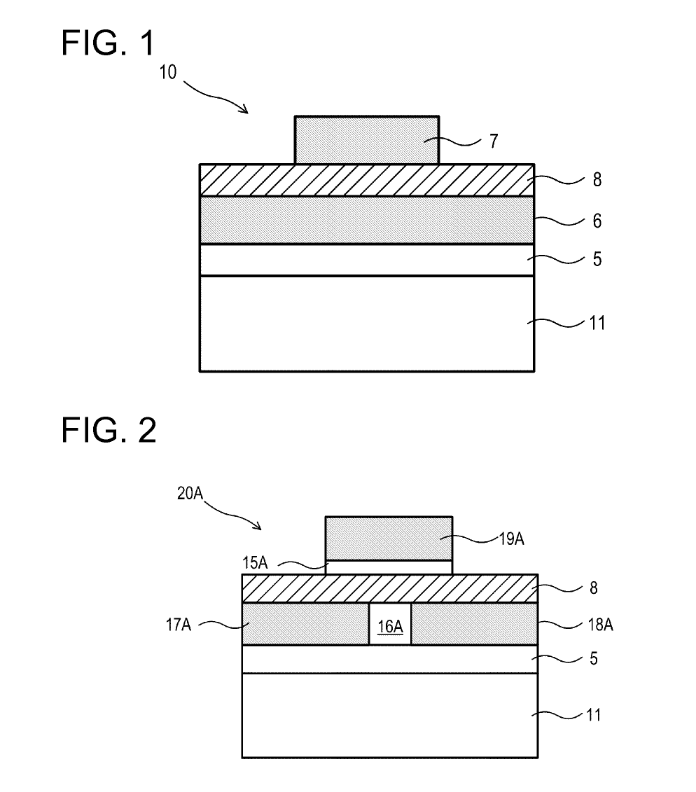

FIG. 1 is a cross-sectional view showing one example of a two-electrode type resistive-switching memory device. A conventional two-electrode type resistive-switching memory device 10 shown in FIG. 1 has a structure in which a lower electrode 5, a resistive-switching insulating film 8, and an upper electrode 7 are stacked in that order, and by applying a voltage pulse between the lower electrode 5 and the upper electrode 7, the resistance of the resistive-switching insulating film 8 can be reversibly changed. The two-electrode type resistive-switching memory device 10 is stacked over the insulating film 5 and a substrate 11.

The method of manufacturing a two-electrode type resistive-switching memory device 10 is described below. First, a silicon oxide film is formed by thermal oxidation as the insulating film 5 on a monocrystalline silicon substrate 11. Then, Al is sputtered onto the silicon oxide film as the lower electrode 5. Then, a hafnium oxide film approximately 3 nm in thickness, for example, is formed evenly as the resistive-switching insulating film 8 on the lower electrode 5 by atomic layer deposition (ALD). Next, Al is deposited to a thickness of 100 nm on the surface of the resistive-switching insulating film 8 by high vacuum deposition to form the 25 μmφ upper electrode 7.

The IV characteristics of the device are shown in FIG. 1. When 2.5 V is applied through a 28 μA current regulating diode, the device switches from high resistance to low resistance. If the voltage is increased to 2 V while bypassing the current regulating diode, the OFF current reaches 18 mA before the voltage reaches 1 V, which causes a unipolar operation, resulting in the device suddenly returning to a high resistance state. The OFF current of the comparison example is approximately four orders of magnitude greater than that of an embodiment of the present invention, which makes clear the advantage of the three-electrode type resistive-switching memory device of the present invention in consuming less power.

(2) Configuration of Three-Electrode Type Resistive-Switching Memory Device

FIG. 2 is a cross-sectional view showing one example of a three-electrode type resistive-switching memory device. A resistive-switching memory device 20A shown in FIG. 2 is of a top gate type. The three-electrode type resistive-switching memory device 20A includes a source electrode 17A, a drain electrode 18A, and a gate electrode 19A, and a resistive-switching insulating film 8 is disposed between the source electrode 17A, the drain electrode 18A, and the gate electrode 19A. An alumina insulating film 15A is provided between the source electrode 17A, the drain electrode 18A, and the gate electrode 19A to prevent short-circuiting therebetween. The alumina insulating film 16A insulates the source from the drain. When the potential of the source electrode 17A is increased, electrons tunnel into the resistive-switching insulating film 8 to charge it, which causes a decrease in resistance therein, thereby turning ON the resistive-switching insulating film 8.

If the potential of the gate electrode 19A is greater than the potential of the source electrode 17A and the drain electrode 18A, the electrons that had formed a conduction band in the resistive-switching insulating film 8 by becoming delocalized are extracted to the source electrode 17A and the drain electrode 18A by field effect, which reduces the number of electrons in the resistive-switching insulating film 8, and thus, the electrons are localized and the resistive-switching insulating film 8 is turned OFF. By using the field effect to turn OFF the resistive-switching memory, it is possible to greatly reduce the OFF current, and the operating principles thereof will be described later.

After forming a bottom gate electrode to a thickness of 500 nm by DC sputtering Al on the Si substrate, the surface of which has SiO₂, Al₂O₃ is AC coated thereon to a thickness of 50 nm, an AlOₓ film is formed to a thickness of 30 nm by simultaneously sputtering Al and Al₂O₃ thereon (Al: DC 5W, Al₂O₃: AC 200W, in an Ar atmosphere), and then, Al₂O₃ is AC coated thereon to a thickness of 50 nm. After plasma forming SiO₂ to a thickness of 200 nm as a passivation film, a photoresist film is coated and then a gate electrode extraction hole that is 2 μm² in area is dry etched down to the Al film using a photomask 1, and similarly, a photomask 2 is used to dry etch the portion where the source electrode and the drain electrode are to be formed (gap between electrodes: 0.6 μm) down to the AlOₓ film. Then, Al is DC sputtered to a thickness of 200 nm, and the source electrode and the drain electrode are formed using a photomask 3.

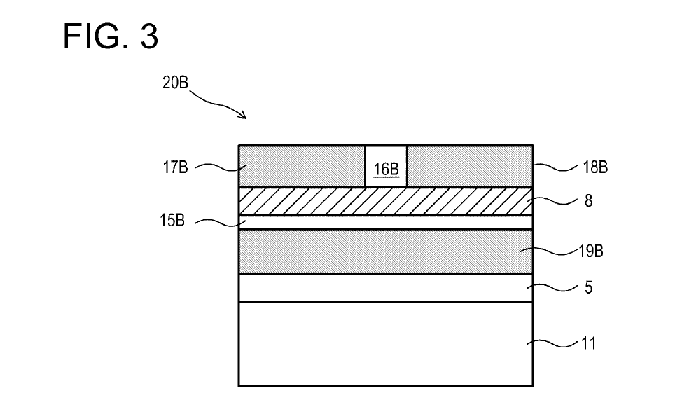

FIG. 3 is a cross-sectional view showing an example of a resistive-switching memory device of another embodiment. A resistive-switching memory device 20B shown in FIG. 3 is of a bottom gate type. The resistive-switching memory device 20B includes a source electrode 17B, a drain electrode 18B, and a gate electrode 19B, and a resistive-switching insulating film 8 disposed between the source electrode 17B and drain electrode 18B, and the gate electrode 19B. An alumina insulating film 16B is provided between the source electrode 17B and the gate electrode 18B in order to prevent short-circuiting therebetween. Also, an alumina insulating film 15B is provided in order to prevent short-circuiting between the gate electrode 19B, and the source electrode 17B and drain electrode 18B.

(3) Operating Principles of Resistive-Switching Memory Device

In Non-Patent Document 2, the atomic and electron structure relating to the oxygen vacancy in the amorphous alumina is explained by first-principles calculations. The first-principles calculations are based on the density functional theory (DFT) within the local density approximation (LDA) and the plane-wave pseudo-potential method. The inventors of the present invention studied the electron state in the ON/OFF state determined by the first-principles calculation results of Non-Patent Document 2 by thermally stimulated current measurement. As a result, electrons trapped in oxygen vacancies (Vo) in an aluminum oxide (hereinafter AlOₓ) film having a high density of oxygen vacancies (hereinafter, Vo electrons) were found to be at an energy of 0.17 to 0.41 eV below that of the conduction band. The donor level of a typical n-type Si semiconductor is below 0.029 eV, and thus, the donor level electrons are excited by the conduction band at room temperature, whereas Vo electrons are at a deeper level, and thus, need to become hot electrons in order to be excited by the conduction band. Thus, in order to provide the Vo electrons with this activation energy through current, there was a need to increase the current density. In the present embodiment, the resistive-switching insulating film, which has a high density of oxygen vacancies, is not limited to an aluminum oxide film, and a metal oxide film including a metal other than a transition metal may be used. This is discussed in “(4) Metal Oxide Film Including Metal Other than Transition Metal.”

According to the first-principles calculation results of Non-Patent Document 2, activation energy is needed in order for Vo electrons to become hot electrons in an ON state. In order to solve this problem, electrons can be extracted from the three-electrode type resistive-switching memory devices 20A and 20B without the need for hot electrons. In other words, electrons can be directly extracted to the electrodes by an electric field in the three-electrode type resistive-switching memory devices 20A and 20B. The operating principles thereof will be described in detail below.

If, in the three-electrode type resistive-switching memory device, a voltage at or above a threshold is applied between the source electrode and the drain electrode in the ON state in a manner similar to the two-electrode type resistive-switching memory device, electrons that have undergone Fowler-Nordheim tunneling through the Schottky barrier are injected into the oxygen vacancies of the resistive-switching insulating film, which forms a Vo conduction band, thereby turning ON the device. If, during the ON operation, the potentials of the source electrode and the drain electrode are both lowered by the same voltage (3 V, for example) with respect to the gate potential, then electrons are extracted to the source electrode and the drain electrode, which turns OFF the device.

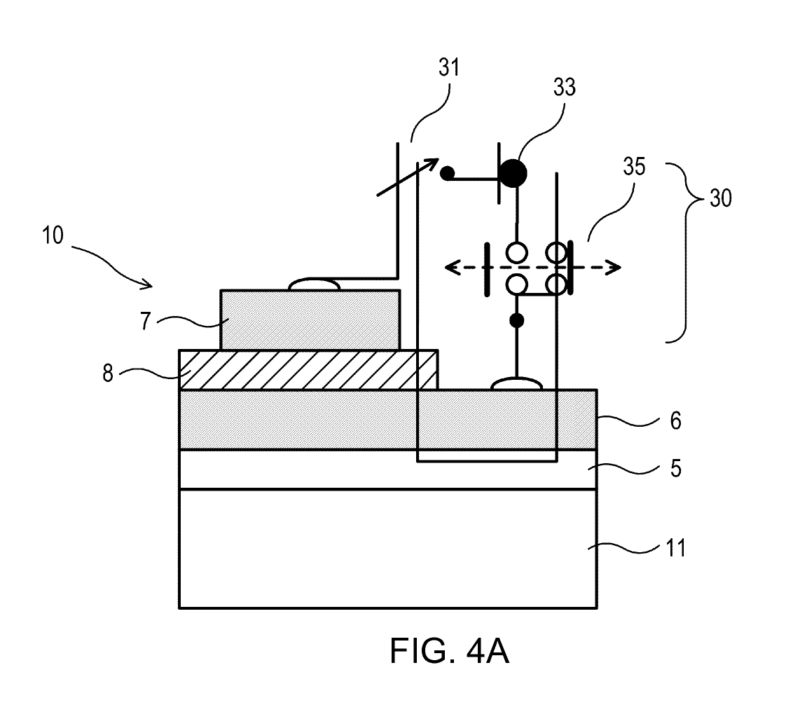

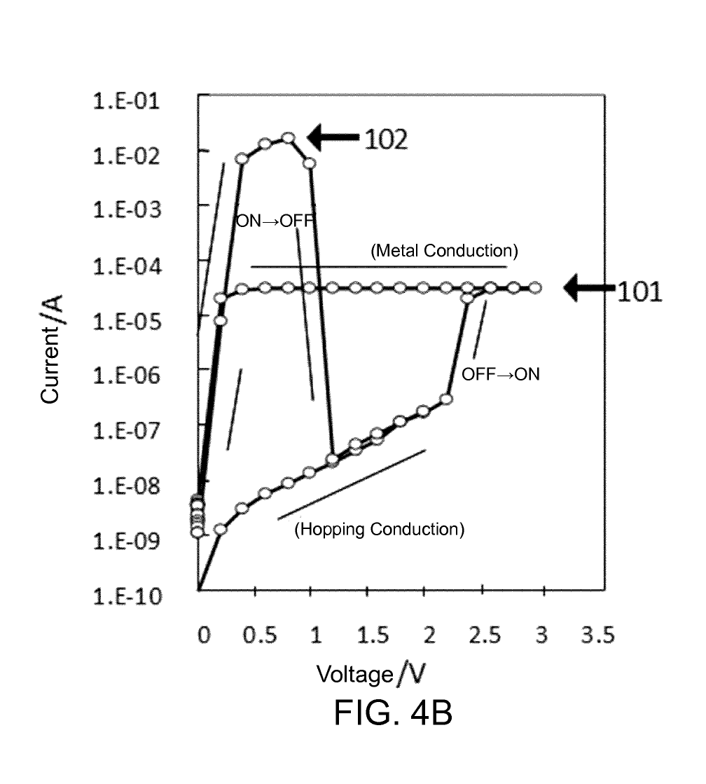

FIG. 4A shows an example of a two-electrode type resistive-switching memory device provided with a circuit for measuring current-voltage (IV) characteristics. A measurement circuit 30 has a power source 31, a current regulating diode 33 that regulates the current, and a switch 35 that performs switching of the diode. The current limit of the current regulating diode 33 is 28 μA.

FIG. 4B shows an example of IV characteristics of the two-electrode type resistive-switching memory device. The operation of the two-electrode type resistive-switching memory device will be described with reference to FIGS. 4A and 4B. First, voltage is applied to the switch 35 through the current regulating diode 33, the current regulating diode 33 regulating the current. If the voltage reaches a threshold (2.5 V), the resistive-switching insulating film 8 turns ON, which changes it from a high resistance state to a low resistance state (101). Next, a voltage is applied to the switch 35 in the ON state while bypassing the current regulating diode 33, which causes an 18 mA OFF current to flow at 1 V, which changes the resistive-switching insulating film 8 to the OFF state by switching it from a low resistance state to a high resistance state.

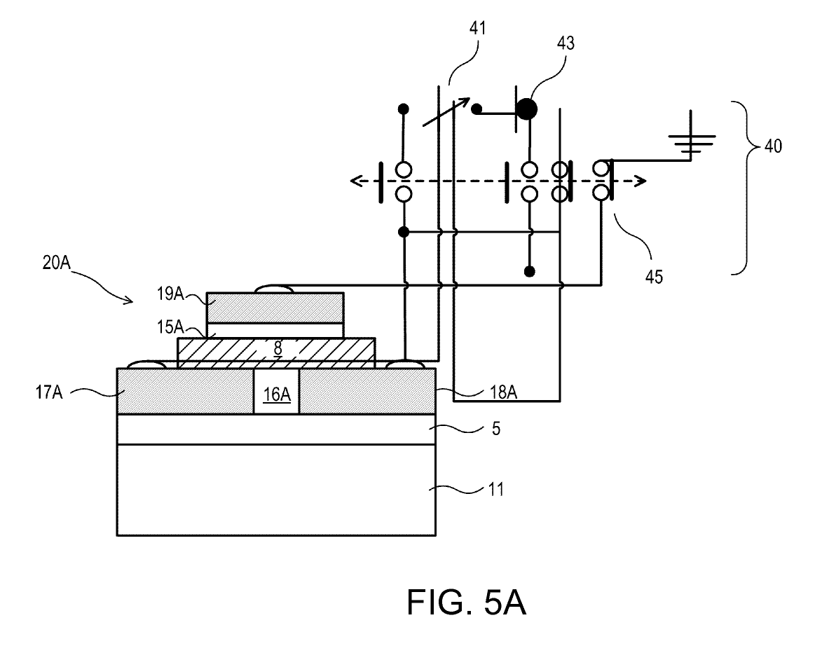

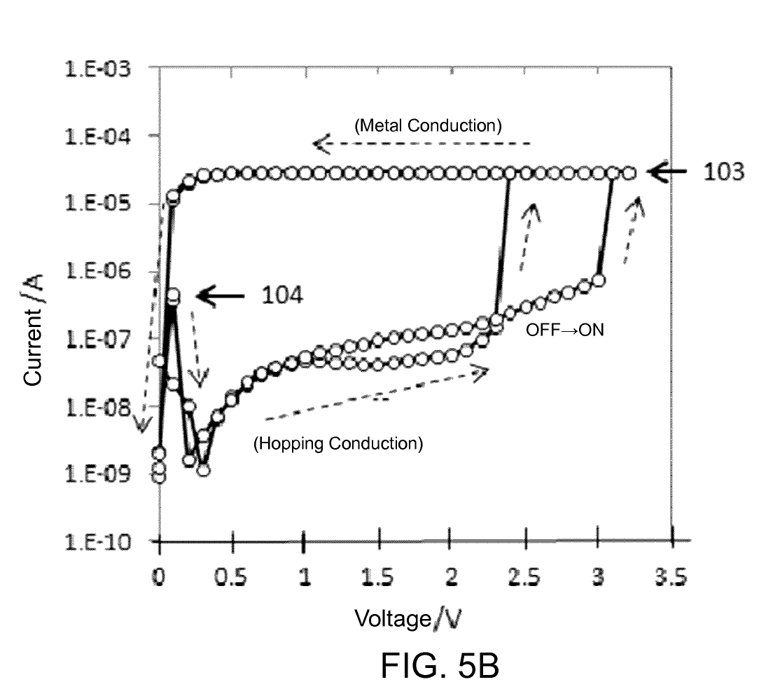

FIG. 5A shows an example of a three-electrode type resistive-switching memory device provided with a circuit for measuring IV characteristics. A measurement circuit 40 has a power source 41, a current regulating diode 43 that regulates the current, and a switch 45 that performs switching on the diode. The current limit of the current regulating diode 43 is 28 μA. The measurement circuit 40 causes voltages shown in Table 1 to be applied to the source electrode, the drain electrode, and the gate electrode to perform writing, deletion, and reading.

TABLE 1
Voltage Applied when Writing, Deleting, or Reading
Three-Electrode Type Resistive-switching memory

| | Applied Voltage | | | Current |
|---|---|---|---|---|
| | | | Gate | Regulating |
| | Source Electrode | Drain Electrode | Electrode | Diode |
| Writing | +3 V | 0 V | Grounded | In Use |
| Deletion | +3 V | +3 V | 0 V | Bypassable |
| Reading | +1 V | 0 V | Grounded | In Use |

FIG. 5B shows an example of IV characteristics of the three-electrode type resistive-switching memory device. The operation of the three-electrode type resistive-switching memory device will be described with reference to FIGS. 5A and 5B. First, voltage is applied to the switch 35 through the current regulating diode 33, the current regulating diode 33 regulating the current. The gate electrode is grounded. In this example, if the voltage between the source and drain is increased to 2 to 3V, the resistive-switching memory device changes from a high resistance state to a low resistance state (103). Next, the switch 35 performs switching such that the voltage to both the source and drain electrodes is 3V and the gate electrode potential is 0V, which returns the resistive-switching insulating film 8 to a high resistance state (104). At this time, the OFF current has not been precisely measured but it is thought that the minute current of 0.7 μA detected in the second cycle of the 0.1V voltage is a portion of the OFF current.

Thus, it can be seen that the OFF current is dramatically reduced in the three-electrode type resistive-switching memory device as compared to the two-electrode type resistive-switching memory device.

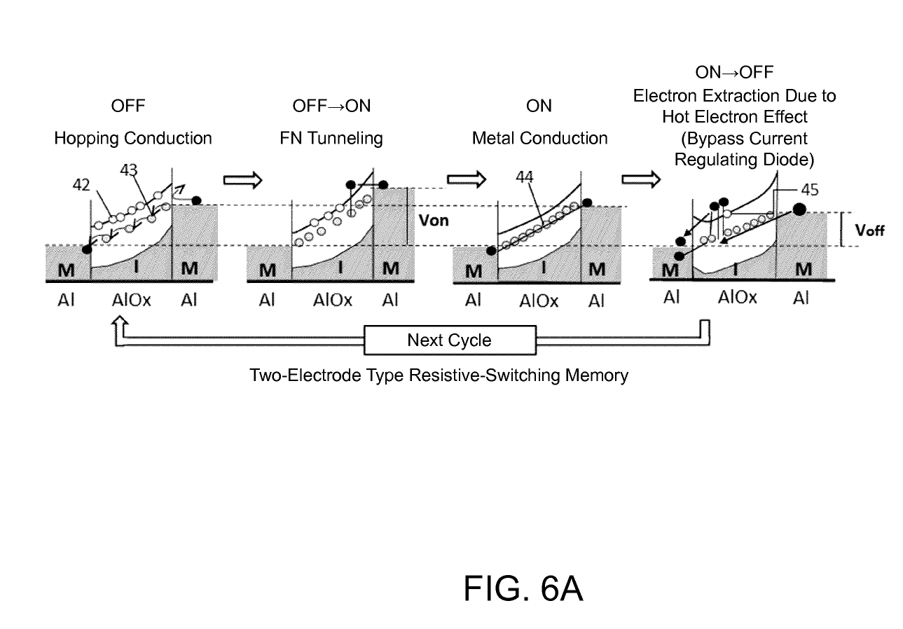

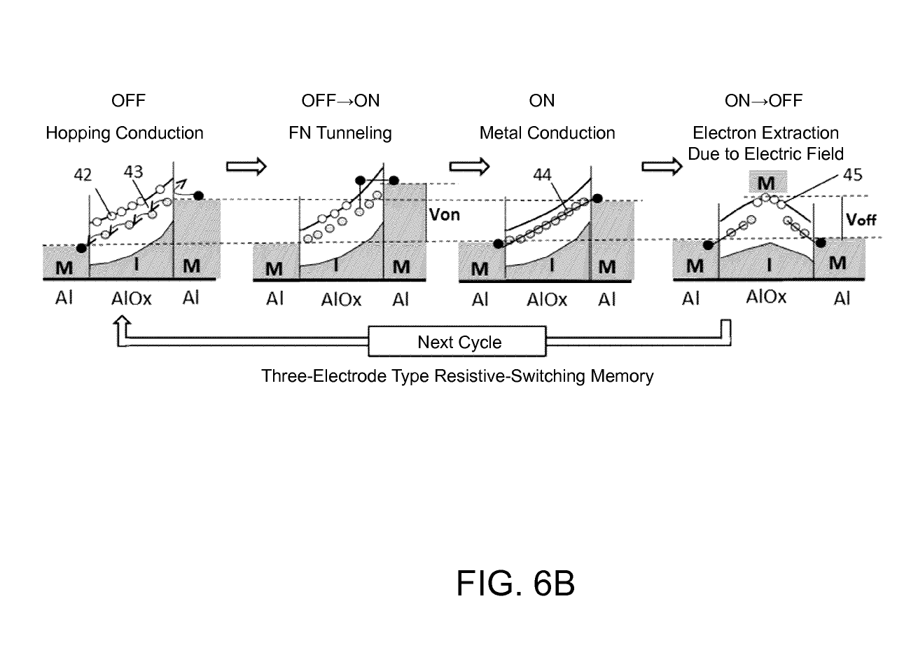

FIG. 6A is a drawing for describing the ON/OFF mechanism of a two-electrode type resistive-switching memory device. FIG. 6B is a drawing for describing the ON/OFF mechanism of a three-electrode type resistive-switching memory device. The reference character 42 represents a vacancy Vo (Vo where no electrons are present), 43 represents a Vo where one electron is localized (an insulation state in which a minute current flows due to hopping conduction), 44 represents a Vo where one electron is delocalized (metal conduction state in which a conduction band is formed), and 45 represents a vacancy Vo that has formed due to electron extraction (a state in which the Al ions in the vicinity of the Vo undergo structural relaxation, resulting in the energy level of the Vo increasing, causing the Vo to merge with the lower end of the conduction band).

According to the Vo band model determined by the first-principles calculation, whether the two-electrode type resistive-switching memory or the three-electrode type resistive-switching memory is used, the ON mechanism is such that electrons undergoing Fowler-Nordheim (FN) tunneling through the Schottky barrier formed between the metal (Al) and the metal oxide film (AlOₓ) fill the Vo, and when the Vo electron density is 10²¹ cm⁻³ or greater, the Vo electrons form a band across an area, which causes the resistive-switching memory to turn to the metal conduction state (ON) shown in the (ON) column.

On the other hand, the OFF mechanism is completely different between the two-electrode type resistive-switching memory and the three-electrode type resistive-switching memory. As shown in “ON→OFF” in FIG. 6B, when a large OFF current flows through the two-electrode type resistive-switching memory, the electrons become hot electrons and the movement energy thereof increases, which causes some of the electrons to be excited by the conduction band thereabove, which causes the overlap in wave functions of the electrons in that position to be cut off. As a result, the electrons below the cut-off position are extracted to the electrodes due to the electric field. Some of the electrons excited by the conduction band lose energy and fill in the oxygen vacancies again, but the majority of the electrons flow to the drain electrode, and in the system as a whole, the number of electrons filling in the oxygen vacancies are reduced and the Vo electrons are localized, which causes the band to disappear, putting the system in a band insulator state (OFF). The reason for this manner of observation is because the mechanism progresses sequentially at a high speed at or below 10 ns, and thus, observation and control are both difficult.

By contrast, the three-electrode type resistive-switching memory has a simple OFF mechanism in which, as shown in “ON→OFF” in FIG. 6B, the Vo electrons in the ON state are extracted to the source and drain electrodes by the effect of the electric field from the gate voltage, thereby reducing the number of Vo electrons and localizing them, which causes the band to disappear and the resistive-switching memory to enter a band insulator (OFF) state. In other words, an OFF current with a high current density for forming hot electrons is unnecessary, and the OFF mechanism can be controlled by the gate voltage.

Based on the knowledge obtained in order to ascertain the operating principles of the resistive-switching memory by the first-principles calculation results in Non-Patent Document 2, the aluminum oxide film used for the resistive-switching insulating film needs have a Vo density of 2×10²¹ cm⁻³ or greater. If the Vo density is 10¹⁹ to 10²⁰ cm⁻³, then even if every Vo were filled with an electron, the wave functions of the Vo electrons overlap to an insufficient degree, which causes a Vo band not to be formed, which means that a metal conduction state does not occur. In such a case, as Hickmott reports in Non-Patent Document 3 and Non-Patent Document 4, if the applied voltage increases to the threshold or greater, then the current increases momentarily, but the resistive-switching insulating film does not switch to a low resistance state, and if the voltage is increased even further, then the current decreases and the resistive-switching memory reverts to the high resistance state, this phenomenon being the so-called negative resistance. If the number of oxygen atoms in a supercell of Al₄₈O₇₃ according to a first-principles calculation is reduced by 2 oxygen atoms from 73, it was found that an overlap in wave function in the Vo electrons due to electron injection occurs, which can form a Vo band. Based on the simulation results, the Vo density necessary for switching is 2×10²¹ cm⁻³ determined by formula (1), and the order thereof matches the number of electrons calculated by thermally stimulated current measurement. At a Vo density of 10¹⁹ to 10²⁰cm⁻³ in which Hickmott found the negative resistance, there is no overlap in wave function among Vo electrons, but if the density is at or above 2×10²¹ cm⁻³, then an overlap in wave function of the Vo electrons occurs, which causes the resistive-switching memory to switch to the low resistance state.

2÷73×10²³=2×10²¹ cm⁻³(10²³:Avogadro constant) (1)

The OFF mechanism of the three-electrode type resistive-switching memory device clearly differs from that of a simple field effect transistor. In a field effect transistor, if a sufficient positive potential is applied to the gate electrode, then this positive potential electrostatically draws a negative charge towards the top of the semiconductor, and repels holes for a large number of carriers from the surface of the substrate. If the potential applied to the gate increases, then the concentration of the small number of carrier electrons at the boundary between the insulating layer and the substrate increases, and eventually matches the density of the holes for the large number of carriers. If a sufficiently large potential is applied to the gate, then the density of electrons at the surface exceeds the density of holes, thereby forming a so-called inversion layer. The inversion layer charge at the boundary between the insulating layer and the semiconductor provides a connective channel between source and drain, and a current flows between these two electrodes due to a potential difference therebetween. In such a case, the device is said to be ON, and the gate voltage necessary to allow conduction is known as the threshold voltage. On the other hand, prior to inversion, there is no conduction in the channel, which means that current cannot flow therethrough, and thus, the transistor is in an OFF state.

In a field effect transistor, the electrons dispersed throughout the semiconductor gather directly below the gate insulating film due to the gate voltage, thus forming an inversion layer, which forms a connective channel, and if the gate voltage is turned OFF, then the electrons naturally disperse throughout the semiconductor as they were originally, which causes the connective channel to disappear.

On the other hand, in the three-electrode type resistive-switching memory device, the connective channel is formed by injecting electrons from outside the device into the resistive-switching insulating film through the electrodes, thereby increasing the number of electrons therein to form a connective channel. These injected electrons are captured by the oxygen vacancies and therefore energetically stable, making the device non-volatile. When turning OFF the device, a gate voltage that is high with respect to the potential of the source and drain electrodes is applied, and the resulting electric field causes the electrons captured by the oxygen vacancies to be extracted to outside of the device through the source and drain electrodes, thereby reducing the number of electrons therein, which localizes the electrons and removes the connective channel, which results in the OFF state whereby no current flows. In this manner, while the three-electrode resistive-switching memory device has a gate electrode like field effect transistors, the three-electrode type resistive-switching memory device differs fundamentally from the field effect transistor in terms of volatility or non-volatility, and the operating mechanism thereof also clearly differs therebetween.

(4) Metal Oxide Film Including Metal Other than Transition Metal

As described above with the aluminum oxide film, the resistive-switching insulating film of the present embodiment has oxygen vacancies. However, simply having oxygen vacancies is insufficient. If, for example, Sn is used, there are multiple bonding states with oxygen such as SnO, SnO₂, and SnO₃, and thus, even if there are oxygen vacancies therein, the change in bonding state between the injected or extracted electrons, Sn, and O is balanced out, which means that the number of electrons at the oxygen vacancies (oxygen holes) does not increase. In the resistive-switching memory device of the present embodiment, switching occurs between insulation and conduction due to electrons being extracted or injected between the oxygen holes (Vo) and the electrodes, according to reactions 1 and 2 below.

Reaction 1: Vo2++e−→Vo1+

An electron is injected to the empty Vos (Vo2+), which results in Vo1+, and if the number of Vo1+increases, then a conduction band is formed, which results in conduction.

Reaction 2: Vo1+−e−→Vo2+. If an electron is extracted from Vo resulting in Vo2+, then the conduction band is cut off, resulting in an insulating state.

In other words, it is preferable that the injection or extraction of electrons occur only between the Vo and the electrodes, and if the bonding state between Sn and O changes, then this results in a disturbance to the reactions 1 and 2. A similar phenomenon occurs when a transition metal, which undergoes changes in valence, is used. For example, in Ta, which undergoes a change in valence between four and five, can form both TaO₂ and Ta₂O₅, and the following chemical reaction in which O moves between electrodes occurs simultaneously to the injection and extraction of electrons.

Ta₂O₅+2e− (conductive state)⇄2TaO₂2O— (insulating state)

The ReRAM in Patent Document 3 has the advantage of very low power consumption. However, because the operation involves movement of O ions, the number of times the memory can be rewritten is 10⁶, which is similar to that of flash memory, which means that the durability thereof is much less than that of DRAM. In the present embodiment, only the number of electrons changes, which is a physical change, and no chemical change such as O ions moving occurs, and thus, the number of times the memory can be rewritten, in principle, increases. In other words, Al, Zn, and In are suited to being used in the metal oxide film in the resistive-switching insulating film of the present embodiment because these are elements that do not undergo valence change due all inner electron shells being full, and the bonding state with oxygen being stable. Even if the conductivity is increased by adding transition metals such as Ti or Ni, there is a need to reduce the leakage current in the OFF state by keeping the amount added thereof at or below 3 wt %.

The embodiment described above is merely a typical example, and it is apparent those skilled in the art that combinations, modifications, and variations of the components of the respective embodiments can be made. Thus, it is apparent to those skilled in the art that various modifications can be made to the embodiments above without deviating from the gist of the present invention or from the scope of the invention defined by the claims.

### DESCRIPTION OF REFERENCE CHARACTERS

5 lower electrode

7 upper electrode

8 resistive-switching insulating film

10 two-electrode type resistive-switching memory device

11 substrate

16A, 16B alumina insulating film

17A, 17B source electrode

18A, 18B drain electrode

19A, 19B gate electrode

20A, 20B three-electrode type resistive-switching memory device

30 measurement circuit for two-electrode type resistive-switching memory device

31, 41 power source

33, 43 current regulating diode

35, 45 switch

40 measurement circuit for three-electrode type resistive-switching memory device

1. A resistive-switching memory device, comprising:
a resistive-switching insulating film;
a source electrode disposed on a first main surface of the resistive-switching insulating film;
a drain electrode disposed on the first main surface; and
a gate electrode disposed on a second main surface of the resistive-switching insulating film opposite to the first main surface.

2. The resistive-switching memory device according to claim 1, further comprising: an insulating film between the source electrode and the drain electrode.

3. The resistive-switching memory device according to claim 1, wherein said resistive-switching memory device is configured such that deletion of data is performed by setting a potential of the gate electrode greater than a potential of the source electrode and the drain electrode.

4. The resistive-switching memory device according to claim 1, wherein the source electrode and the drain electrode are arranged in a direction parallel to a planar direction of the resistive-switching insulating film.

5. The resistive-switching memory device according to claim 1, wherein the resistive-switching insulating film is an aluminum oxide film or a metal oxide film of a metal other than a transition metal, and has oxygen vacancies at a density of 2×10²¹ cm⁻³ or greater.

6. The resistive-switching memory device according to claim 5, wherein the transition metal is Zn, In, or Ga.

7. The resistive-switching memory device according to claim 2, wherein said resistive-switching memory device is configured such that deletion of data is performed by setting a potential of the gate electrode greater than a potential of the source electrode and the drain electrode.

8. The resistive-switching memory device according to claim 2, wherein the resistive-switching insulating film is an aluminum oxide film or a metal oxide film of a metal other than a transition metal, and has oxygen vacancies at a density of 2×10²¹ cm⁻³ or greater.

9. The resistive-switching memory device according to claim 3, wherein the resistive-switching insulating film is an aluminum oxide film or a metal oxide film of a metal other than a transition metal, and has oxygen vacancies at a density of 2×10²¹ cm⁻³ or greater.

10. The resistive-switching memory device according to claim 4, wherein the resistive-switching insulating film is an aluminum oxide film or a metal oxide film of a metal other than a transition metal, and has oxygen vacancies at a density of 2×10²¹ cm⁻³ or greater.

11. The resistive-switching memory device according to claim 7, wherein the resistive-switching insulating film is an aluminum oxide film or a metal oxide film of a metal other than a transition metal, and has oxygen vacancies at a density of 2×10²¹ cm⁻³ or greater.

12. The resistive-switching memory device according to claim 8, wherein the transition metal is Zn, In, or Ga.

13. The resistive-switching memory device according to claim 9, wherein the transition metal is Zn, In, or Ga.

14. The resistive-switching memory device according to claim 10, wherein the transition metal is Zn, In, or Ga.

15. The resistive-switching memory device according to claim 11, wherein the transition metal is Zn, In, or Ga.
